(19) United States
(12) Patent Application Publication
(10) Pub. No.: US 2012/0193129 A1
(43) Pub. Date: Aug. 2, 2012

(54) PROCESS FOR PRODUCING GLASS CLOTH SUBSTRATE AND PRINTED WIRING BOARD

(75) Inventors: Toyonari Ito, Tsukuba-shi (JP); Shohei Azami, Tsukuba-shi (JP)

(73) Assignee: SUMITOMO CHEMICAL COMPANY, LIMITED, Chuo-ku, Tokyo (JP)

(21) Appl. No.: 13/500,082

(22) PCT Filed: Oct. 4, 2010
(86) PCT No.: PCT/JP2010/067703

§ 371 Date: Apr. 4, 2012

(30) Foreign Application Priority Data
Oct. 9, 2009 (JP) 2009-234748

(51) Int. Cl. H05K 1/03; B05D 5/12

(52) U.S. Cl. 174/254; 427/99.2

(57) ABSTRACT

The present invention provides a process for producing a glass cloth substrate including: an impregnating step of impregnating a surface-treated glass cloth with a liquid composition including a solvent and a polyester to obtain a liquid composition-impregnated glass cloth, and a substrate preparing step of removing the solvent from the liquid composition in the liquid composition-impregnated glass cloth to obtain a glass cloth substrate. According to the present invention, adherability between the liquid crystal polyester and the glass cloth is improved, and the heat resistance at moisture absorption of the glass cloth substrate is improved.

### TECHNICAL FIELD

The present invention relates to a process for producing a glass cloth substrate used as an insulating layer of a printed wiring board (printed substrate, printed circuit board, etc.) which is incorporated into a variety of electric equipments such as a cellular phone, a personal computer, and a digital appliance, and a printed wiring board equipped with this glass cloth substrate.

### BACKGROUND ART

Previously, as this kind of a glass cloth substrate, a glass cloth substrate obtained by impregnating a glass cloth with a liquid crystal polyester solution, and then removing the solvent has been suitably used due to excellent dimensional stability (see, for example, JP-A No. 2004-244621, JP-A No. 2007-146139).

### DISCLOSURE OF THE INVENTION

However, in such a conventional glass cloth substrate, since heat resistance at moisture absorption (e.g., solder heat resistance) was insufficient, a liquid crystal polyester was peeled from the glass cloth in some cases. When such a glass cloth substrate was used as an insulating layer to produce a printed wiring board, the reliance (inter alia, insulating property) and durability of the printed wiring board were reduced in some cases.

Then, in view of such circumstances, one object of the present invention is to provide a process for producing a glass cloth substrate which can improve the heat resistance at moisture absorption of a glass cloth substrate obtained by impregnating the cloth with a liquid crystal polyester solution, and avoid the situation of peeling of the liquid crystal polyester from the glass cloth, and another object thereof is to provide a printed wiring plate having high reliance and durability with the use of this glass cloth substrate.

In order to attain such objects, the present inventors have enhanced the heat resistance at moisture absorption of a glass cloth substrate, and improved adherability between a liquid crystal polyester and a glass cloth by surface-treating the glass cloth using a silane compound prior to impregnation of the glass cloth with the liquid crystal polyester, resulting in completion of the present invention.

That is, the present invention provides a process for producing a glass cloth substrate including a glass cloth which has been subjected to a surface treatment using a silane compound having a methacryloyloxy group, and a liquid crystal polyester contained in the glass cloth, comprising:

an impregnating step of impregnating the surface-treated glass cloth with a liquid composition including a solvent and the liquid crystal polyester to obtain a liquid composition-impregnated glass cloth, and

a substrate preparing step of removing the solvent from the liquid composition in the liquid composition-impregnated glass cloth to obtain a glass cloth substrate.

The liquid crystal polyester is preferably a liquid crystal polyester having a structural unit shown by the following formula (1), a structural unit shown by the following formula (2), and a structural unit shown by the following formula (3), the content of the structural unit shown by the formula (1) being 30 to 50 mol %, the content of the structural unit shown by the formula (2) being 25 to 35 mol %, and the content of the structural unit shown by the formula (3) being 25 to 35 mol % based on the total of all structural units;

—O—Ar¹—CO— (1)

—CO—Ar²—CO— (2)

—X—Ar³—Y— (3)

wherein, Ar¹ represents a phenylene group or a naphthylene group, Ar² represents a phenylene group, a naphthylene group or a group represented by the following formula (4), Ar³ represents a phenylene group or a group represented by the formula (4), and X and Y each independently represent O or NH. A hydrogen atom bonded to the aromatic ring of each Ar¹, Ar² and Ar³ may be substituted with a halogen atom, an alkyl group or an aryl group;

—Ar¹¹—Z—Ar¹²— (4)

wherein, Ar¹¹ and Ar¹² each independently represent a phenylene group or a naphthylene group, and Z represents O, CO or SO₂.

Further, at least one of X and Y in the structural unit shown by the formula (3) is preferably NH.

Further, the liquid crystal polyester is preferably a liquid crystal polyester having a structural unit derived from a compound selected from the group consisting of p-hydroxybenzoic acid and 2-hydroxy-6-naphthoic acid as the structural unit shown by the formula (1), having a structural unit derived from a compound selected from the group consisting of terephthalic acid, isophthalic acid and 2,6-naphthalenedicarboxylic acid as the structural unit shown by the formula (2), and having a structural unit derived from p-aminophenol as the structural unit shown by the formula (3).

The present invention provides a printed wiring board comprising a glass cloth substrate obtained by the process for producing a glass cloth substrate and a conductor layer, wherein the glass cloth substrate has a first surface and a second surface present on the rear side of the first surface, and the glass cloth substrate has the conductor layer on the first surface.

The present invention provides the above printed wiring board further comprising a conductor layer laminated on the second surface of the glass cloth substrate.

The present invention provides a printed wiring board comprising a plurality of glass cloth substrates, wherein at least one glass cloth substrate is a glass cloth substrate obtained by the process for producing a glass cloth substrate.

According to the present invention, a glass cloth which is subjected to a surface treatment using a silane compound having a methacryloyloxy group prior to impregnation of the glass cloth with a liquid crystal polyester is used, and adherability between the liquid crystal polyester and the glass cloth is improved. For this reason, the heat resistance at moisture absorption of the glass cloth substrate can be improved, and the situation of peeling of the liquid crystal polyester from the glass cloth can be avoided.

By producing a printed wiring board using such a glass cloth substrate, it becomes possible to provide a printed wiring board having high reliance and durability.

### BRIEF DESCRIPTION OF THE DRAWINGS

FIG. 1 is a step view showing a process for producing a printed wiring board according to an embodiment 1 of the present invention, (a) is a view showing a glass cloth preparing step, (b) is a view showing a liquid composition impregnating step, (c) is a view showing a substrate preparing step, (d) is a view showing a conductor pressure-attaching step, and (e) is a view showing a patterning step.

### BEST MODE FOR CARRYING OUT THE INVENTION

### Embodiment 1 of the Invention

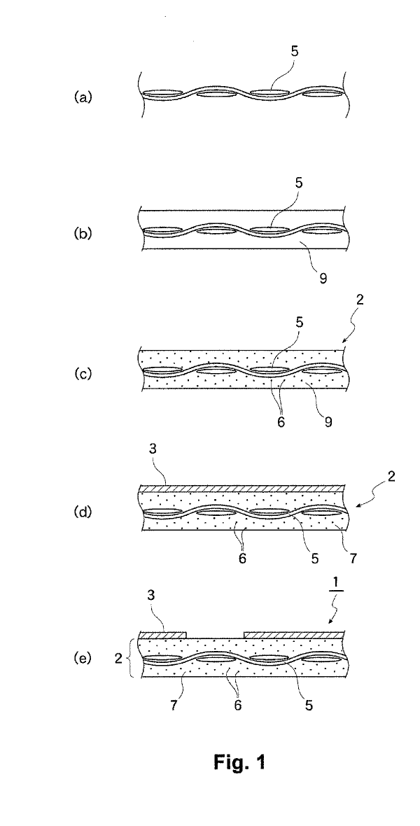

FIG. 1 shows an embodiment 1 of the present invention. In this embodiment 1, a monolayer-type printed wiring board 1 is shown, in which one layer of the glass cloth substrate of the present invention is used as an insulating layer, and a conductor layer is laminated on one surface thereof. The configuration and production process thereof will be sequentially described. In addition, in FIG. 1, since a FIGURE is shown for easy understanding, the ratio of dimensions (thickness, etc.) of respective constituents is not necessarily shown correctly.

First, a configuration of the printed wiring board 1 will be described.

This printed wiring board 1, as shown in FIG. 1 (e), has a sheet-like glass cloth substrate 2 of the present invention with a predetermined thickness (e.g., 20 to 250 μm, preferably 50 to 200 μm) as an insulating layer, and a copper foil 3 with a predetermined thickness (e.g., 1 to 70 μm, preferably 3 to 35 μm) as a conductor layer is pasted on a surface (FIG. 1 (e) upper surface) of the glass cloth substrate 2 to form a circuit pattern. The glass cloth substrate 2 includes a glass cloth 5 with a predetermined thickness (e.g., 10 to 200 μm), and a liquid crystal polyester 7 uniformly including a filler 6 is attached to the glass cloth 5.

Herein, it is preferable that the liquid crystal polyester 7 is a polyester having properties of showing optical anisotropy at the time of melting, and forming an anisotropic melt at a temperature of 450° C. or lower. As this liquid crystal polyester 7, a liquid crystal polyester having a structural unit shown by the following formula (1) (hereinafter, referred to as “structural unit (1)”), a structural unit shown by the following formula (2) (hereinafter, referred to as “structural unit (2)”), and a structural unit shown by the following formula (3) (hereinafter, referred to as “structural unit (3)”), the content of the structural unit (1) being 30 to 50 mol %, the content of the structural unit (2) being 25 to 35 mol %, and the content of the structural unit (3) being 25 to 35 mol % based on the total of all structural units, is preferable;

—O—Ar¹—CO— (1)

—CO—Ar²—CO— (2)

—X—Ar³—Y— (3)

wherein, Ar¹ represents a phenylene group or a naphthylene group, Ar² represents a phenylene group, a naphthylene group or a group represented by the following formula (4), Ar³ represents a phenylene group or a group represented by the following formula (4), and X and Y each independently represent O or NH. A hydrogen atom bonded to an aromatic ring of each Ar¹, Ar² and Ar³ may be substituted with a halogen atom, an alkyl group or an aryl group;

—Ar¹¹—Z—Ar¹²— (4)

wherein, Ar¹¹ and Ar¹² each independently represent a phenylene group or a naphthylene group, and Z represents O, CO or SO₂.

Herein, the structural unit (1) is a structural unit derived from aromatic hydroxycarboxylic acid, and examples of the aromatic hydroxycarboxylic acid include p-hydroxybenzoic acid, m-hydroxybenzoic acid, 2-hydroxy-6-naphthoic acid, 2-hydroxy-3-naphthoic acid, and 1-hydroxy-4-naphthoic acid.

The structural unit (2) is a structural unit derived from aromatic dicarboxylic acid, and examples of the aromatic dicarboxylic acid include terephthalic acid, isophthalic acid, 2,6-naphthalenedicarboxylic acid, 1,5-naphthalenedicarboxylic acid, diphenylether-4,4′-dicarboxylic acid, diphenylsulfone-4,4′-dicarboxylic acid, and diphenylketone-4,4′-dicarboxylic acid.

Further, the structural unit (3) is a structural unit derived from aromatic diol, or aromatic amine or aromatic diamine having a phenolic hydroxyl group (phenolic hydroxy group).

Examples of the aromatic diol include hydroquinone, resorcin, 2,2-bis(4-hydroxy-3,5-dimethylphenyl)propane, bis(4-hydroxyphenyl)ether, bis-(4-hydroxyphenyl)ketone, and bis-(4-hydroxyphenyl)sulfone. Examples of the aromatic amine having a phenolic hydroxyl group include p-aminophenol and m-aminophenol, and examples of the aromatic diamine include 1,4-phenylenediamine and 1,3-phenylenediamine.

The liquid crystal polyester 7 is soluble to a solvent. The phrase “soluble to a solvent” means that the liquid crystal polyester is dissolved in a solvent at a concentration of 1 mass % or more at a temperature of 50° C.

A soluble liquid crystal polyester preferably include, as the structural unit (3), a structural unit derived from aromatic amine having a phenolic hydroxyl group and a structural unit derived from a compound selected from the group of aromatic diamine is preferable. That is, when the soluble liquid crystal polyester includes a structural unit in which at least one of X and Y is NH (structural unit represented by the formula (3′), hereinafter, referred to as “structural unit (3′)”) as the structural unit (3), there is a tendency that solubility to a suitable solvent (e.g., aprotic polar solvent) described later is excellent and, therefore, this is preferable. Particularly, it is preferable that the structural unit (3′) is used as substantially all structural units (3). The structural unit (3′) is also advantageous in that the production of the glass cloth substrate 2 using a liquid composition 9 described later becomes easier, in addition to an advantage that the solubility of the liquid crystal polyester 7 is made sufficient;

—X—Ar³—NH— (3′)

wherein, Ar³ and X are as defined above.

It is more preferable that the liquid crystal polyester in the present invention includes the structural unit (3′) in a range of 30 to 32.5 mol % based on the total of all structural units, and accordingly, this makes the solubility to a solvent more favorable. The liquid crystal polyester having the structural unit (3′) as the structural unit (3) also has an advantage that the production of the glass cloth substrate 2 using a liquid composition 9 described later becomes further easier, in addition to an advantage that the solubility to a solvent becomes favorable.

The structural unit (1) is preferably included in a range of 30 to 50 mol %, more preferably in a range of 35 to 40 mol % based on the total of all structural units. There is a tendency that the liquid crystal polyester 7 including the structural unit (1) at such a mole fraction is more excellent in solubility to a solvent while liquid crystallinity is sufficiently maintained. Further, also in consideration of availability of aromatic hydroxycarboxylic acid from which the structural unit (1) is derived, as this aromatic hydroxycarboxylic acid, p-hydroxybenzoic acid and 2-hydroxy-6-naphthoic acid are preferable. That is, the liquid crystal polyester used in the present invention includes, as the structural unit (1), a structural unit derived from a compound selected from the group consisting of p-hydroxybenzoic acid and 2-hydroxy-6-naphthoic acid at preferably 30 to 50 mol %, more preferably 35 to 40 mol % based on the total of all structural units.

The liquid crystal polyester in the present invention includes the structural unit (2) preferably in a range of 25 to 35 mol %, more preferably in a range of 30 to 32.5 mol % based on the total of all structural units. There is a tendency that the liquid crystal polyester including the structural unit (2) in such a mole fraction is more excellent in solubility to a solvent while liquid crystallinity is sufficiently maintained. Further, also in consideration of availability of aromatic dicarboxylic acid from which the structural unit (2) is derived, it is preferable that the aromatic dicarboxylic acid is at least one kind compound selected from the group consisting of terephthalic acid, isophthalic acid and 2,6-naphthalenedicarboxylic acid. That is, the liquid crystal polyester used in the present invention includes, as the structural unit (2), a structural unit derived from a compound selected from the group consisting of terephthalic acid, isophthalic acid and 2,6-naphthalenedicarboxylic acid at preferably 25 to 35 mol %, more preferably 30 to 32.5 mol % based on the total of all structural units

It is preferable that the liquid crystal polyester used in the present invention has, as the structural unit (3), a structural unit derived from p-aminophenol at 25 to 35 mol % based on the total of all structural units.

In a point having higher liquid crystallinity, it is preferable to use a liquid crystal polyester having a mole fraction of the structural unit (2) and the structural unit (3) in a range of 0.9/1 to 1/0.9, as expressed by [structural unit (2)]/[structural unit (3)].

Then, a process for producing the liquid crystal polyester 7 will be simply described.

This liquid crystal polyester 7 can be produced by various known processes. When the liquid crystal polyester 7 including the structural unit (1), the structural unit (2) and the structural unit (3), which is a preferable liquid crystal polyester 7, is produced, a process for producing the liquid crystal polyester 7 by converting monomers from which these structural units are derived, into ester forming/amide forming derivatives, followed by polymerization is preferable due to simple operation.

The ester forming/amide forming derivative will be described by way of examples.

Examples of the ester forming/amide forming derivative of a monomer having a carboxyl group, such as aromatic hydroxycarboxylic acid or aromatic dicarboxylic acid, include derivatives in which the carboxyl group becomes a group having high reaction activity such as a haloformyl group or an acyloxycarbonyl group to form an acid halide, an acid anhydride and the like so as to promote reaction producing a polyester or a polyamide, and derivatives in which the carboxyl group forms an ester with alcohols or ethylene glycol so as to produce a polyester or a polyamide by a transesterification/amide interchange reaction or the like.

Examples of the ester forming/amide forming derivative of a monomer having a phenolic hydroxyl group, such as aromatic hydroxycarboxylic acid or aromatic diol, include derivatives in which a phenolic hydroxyl group forms an ester with carboxylic acids so as to produce a polyester or a polyamide by a transesterification reaction.

Examples of the amide forming derivative of a monomer having an amino group, such as aromatic diamine, include derivatives in which an amino group forms amide with carboxylic acids so as to produce a polyamide by an amide interchange reaction.

Among them, from the viewpoint of producing the liquid crystal polyester 7 more conveniently, a process for producing the liquid crystal polyester 7 by acylating aromatic hydroxycarboxylic acid, and a monomer having a phenolic hydroxyl group and/or an amino group such as aromatic diol, aromatic amine having a phenolic hydroxyl group, and aromatic diamine with a fatty acid anhydride to generate an ester forming/amide forming derivative (acylated compound), and thereafter, performing polymerization so that an acyl group of this acylated compound and a carboxyl group of a monomer having a carboxyl group generate a transesterification/amide interchange reaction is particularly preferable.

Such a process for producing the liquid crystal polyester 7 is described, for example, in JP-A No. 2002-220444 or JP-A No. 2002-146003.

In the acylation, the amount of the fatty acid anhydride added is preferably 1 to 1.2-fold equivalent, more preferably 1.05 to 1.1-fold equivalent based on the total of the phenolic hydroxyl group and the amino group. When the amount of the fatty acid anhydride added is less than 1-fold equivalent, there is a tendency that an acylated compound and a raw material monomer are sublimated at polymerization, and the reaction system is easily blocked and, when the amount is more than 1.2-fold equivalent, there is a tendency that the coloration of the resulting liquid crystal polyester 7 becomes remarkable.

For the acylation, reaction at 130 to 180° C. for 5 minutes to 10 hours is preferable, and reaction at 140 to 160° C. for 10 minutes to 3 hours is more preferable.

From the viewpoint of cost and handleability, the fatty acid anhydride used in the acylation is preferably acetic acid anhydride, propionic acid anhydride, butyric acid anhydride, isobutyric acid anhydride or a mixture of two or more kinds selected therefrom, and particularly preferably acetic acid anhydride.

The polymerization subsequent to the acylation is preferably performed at 130 to 400° C. while temperature is raised at a rate of 0.1 to 50° C./minute, and more preferably performed at 150 to 350° C. while temperature is raised at a rate of 0.3 to 5° C./minute.

In the polymerization, it is preferable that an acyl group of the acylated compound is 0.8 to 1.2-fold equivalent of a carboxyl group.

Upon the acylation and/or the polymerization, it is preferable to distill off fatty, acid as a byproduct and an unreacted fatty acid anhydride to the outside of the system by evaporation or the like, in order to shift equilibrium.

In addition, the acylation or polymerization may be performed in the presence of a catalyst. As this catalyst, catalysts which have previously been known as catalysts for polymerizing a polyester can be used, and examples thereof include metal salt catalysts such as magnesium acetate, stannous acetate, tetrabutyl titanate, lead acetate, sodium acetate, potassium acetate, and antimony trioxide, and organic compound catalysts such as N,N-dimethylaminopyridine and N-methylimidazole.

Among these catalysts, heterocyclic compounds containing two or more nitrogen atoms such as N,N-dimethylaminopyridine and N-methylimidazole are preferably used (see JP-A No. 2002-146003).

This catalyst is usually loaded together at the load of a monomer, and is not necessarily required to be removed after the acylation, and when this catalyst is not removed, the acylation can progress to the polymerization as it is.

The liquid crystal polyester 7 obtained by such polymerization can be used as it is in the present invention, but in order to further improve properties of heat resistance and liquid crystallinity, the liquid crystal polyester preferably has more highly molecular weight, and it is preferable to perform solid phase polymerization in order to have high molecular weight. A series of operations in connection with this solid phase polymerization will be described. The liquid crystal polyester 7 having relatively low molecular weight, which is obtained by the polymerization, is taken out, and ground into a powder form or a flake form. Subsequently, solid phase polymerization can be carried out, for example, by the operation of heat-treating the liquid crystal polyester 7 after grinding in the solid phase state at 20 to 350° C. for 1 to 30 hours under the atmosphere of an inert gas such as nitrogen. This solid phase polymerization may be performed while stirring, or may be performed in the standing state without stirring. In addition, from the viewpoint of obtaining the liquid crystal polyester 7 having a preferable flow starting temperature described later, preferable conditions for this solid phase polymerization are described in detail as follows. The reaction temperature is preferably higher than 210° C., and further more preferably in a range of 220° C. to 350° C. It is preferable that the reaction time is selected from 1 to 10 hours.

The liquid crystal polyester 7 used in the present invention, when the flow starting temperature is 250° C. or higher, is preferable in that adherability between the glass cloth substrate 2 and the copper foil 3 is improved. The flow starting temperature mentioned herein refers to temperature at the liquid crystal polyester 7 has a melt viscosity of 4800 Pa·s or lower under a pressure of 9.8 MPa, in the evaluation of melt viscosity with a flow tester. In addition, this flow starting temperature is well-known to a person skilled in the art as a rough standard of the molecular weight of the liquid crystal polyester 7 (see, for example, “Liquid Crystal Polymer-Synthesis/Molding/Application-” edited by Naoyuki KIODE, pp. 95 to 105, CMC Publishing Co., Ltd., published in Jun. 5, 1987).

It is further preferable that the flow starting temperature of the liquid crystal polyester 7 is 250° C. or higher and 300° C. or lower. When the flow starting temperature is 300° C. or lower, since the solubility of the liquid crystal polyester 7 to a solvent becomes more favorable and, in addition, when a liquid composition 9 described later is obtained, the viscosity thereof is not increased remarkably, and therefore there is a tendency that handleability of this liquid composition 9 becomes good. From such a viewpoint, the liquid crystal polyester 7 having a flow starting temperature of 260° C. or higher and 290° C. or lower is further preferable. In addition, in order to control the flow starting temperature of the liquid crystal polyester 7 in such a preferable range, the polymerization condition of the solid phase polymerization may be appropriately optimized.

The filler 6 is contained in the liquid crystal polyester 7 for the purpose of improving dimensional stability, pyroductivity, electrical property and the like, and examples of the filler include inorganic fillers such as silica, alumina, titanium oxide, barium titanate, strontium titanate, aluminum hydroxide, and calcium carbonate; organic fillers such as a cured epoxy resin, a crosslinked benzoguanamine resin, and a crosslinked acrylic polymer; various additives such as an antioxidant and an ultraviolet absorbing agent.

Then, a process for producing this printed wiring board 1 will be described.

First, as shown in FIG. 1 (a), the glass cloth 5 is prepared in a glass cloth preparing step.

This glass cloth 5 is preferably a glass cloth including alkali-containing glass fibers, alkali-free glass fibers, or low dielectric glass fibers. As fibers constituting the glass cloth 5, ceramic fibers including a ceramic other than glass or carbon fibers may be mixed in portion thereof.

Examples of a process for producing the glass cloth 5 including these fibers include a process of dispersing fibers forming the glass cloth 5 in water, adding a paste such as an acrylic resin as necessary, making a sheet with a paper making machine, and drying the paper to obtain a non-woven fabric, and a process using a known weaving machine.

As weaving of fibers, plain weave, satin weave, twill weave, basket weave and the like can be utilized. The weaving density is 10 to 100 fibers/25 mm, and the glass cloth 5 having a mass per unit area of 10 to 300 g/m² is preferably used. The glass cloth 5 has a thickness of usually around 10 to 200 μm, and the glass cloth 5 having a thickness of 10 to 180 μm is further preferably used.

When the glass cloth 5 has been prepared like this, operation progresses to a glass cloth surface treating step, and the glass cloth 5 is subjected to a surface treatment using a silane compound (coupling agent) having a methacryloyloxy group [CH₂═C(CH₃)COO—] in a molecule. Examples of the silane compound include 3-methacryloyloxypropylmethyldimethoxysilane (γ-methacryloyloxypropylmethyldimethoxysilane), 3-methacryloyloxypropyltrimethoxysilane (γ-methacryloyloxypropyltrimethoxysilane), 3-methacryloyloxylpropylmethyldiethoxysilane (γ-methacryloyloxypropylmethyldiethoxysilane), and 3-methacryloyloxypropyltriethoxysilane (γ-methacryloyloxypropyltriethoxysilane).

The surface treatment of this glass cloth 5 may be performed by immersing the glass cloth 5 in the silane compound or a solution thereof, or may be performed by spraying the silane compound or a solution thereof to the glass cloth 5, or may be performed by gasifying the silane compound or a solution thereof, and contacting this with the glass cloth 5. In addition, when a solution of the silane compound is used, drying for removing a solvent may be performed by blowing hot air, or by irradiating the glass cloth with an electromagnetic wave. Preferably, the surface treatment of the glass cloth 5 is performed by immersing the glass cloth 5 in a 0.01 to 2 mass % aqueous solution containing the silane compound, and then heat-treating the glass cloth 5 at 80° C. or higher for 10 minutes to 10 hours. Thereupon, in order to adjust a hydrogen ion concentration (pH), aliphatic acid, a representative of which is acetic acid or the like, may be added. Further, it is also possible to subject the glass cloth 5 to fiber opening processing with a columnar stream or a water stream by a high frequency vibration process, after the surface treatment thereof.

Further, it is also possible to use the glass cloth 5 which is easily available from a market. As the glass cloth 5, various glass cloths as the glass cloth substrate 2 of electronic parts are commercially available, and can be obtained from Asahi Kasei E-materials Corporation, Nitto Boseki Co., Ltd., Arisawa Manufacturing Co., Ltd., UNITIKA LTD. or the like. In addition, in the commercially available glass cloth 5, examples of the glass cloth having a preferable thickness include 1035, 1078, 1086, 2116, and 7628 under the IPC's name.

When the glass cloth 5 has been subjected to a surface treatment like this, operation progresses to a liquid composition preparing step, and a liquid composition 9 including a solvent, the liquid crystal polyester 7 dissolved in this solvent, and the filler 6 dispersed in this liquid crystal polyester 7 is prepared.

In addition, when the above-mentioned preferable liquid crystal polyester 7, particularly, the liquid crystal polyester 7 including the formula structural unit (3′) is used as the liquid crystal polyester 7, this liquid crystal polyester 7 manifests sufficient solubility to an aprotic solvent not containing a halogen atom.

Herein, examples of the aprotic solvent not containing a halogen atom include ether-based solvents such as diethyl ether, tetrahydrofuran, and 1,4-dioxane; ketone-based solvents such as acetone and cyclohexanone; ester-based solvents such as ethyl acetate; lactone-based solvents such as γ-butyrolactone; carbonate-based solvents such as ethylene carbonate and propylene carbonate; amine-based solvents such as triethylamine and pyridine; nitrile-based solvents such as acetonitrile and succinonitrile; amide-based solvents such as N,N-dimethylformamide, N,N-dimethylacetamide, tetramethylurea, and N-methylpyrrolidone; nitro-based solvents such as nitromethane and nitrobenzene; sulfur-based solvents such as dimethyl sulfoxide and sulfolane; phosphorus-based solvents such as hexamethylphosphoric acid amide and tri-n-butylphosphoric acid. In addition, the solubility of the above-mentioned liquid crystal polyester 7 to a solvent refers to the fact that the liquid crystal polyester is soluble to at least one aprotic solvent selected therefrom.

In order to make the degree of solubility of the liquid crystal polyester 7 to a solvent further favorable, to thereby make it easy to obtain the liquid composition 9, it is preferable to use, among the exemplified solvents, an aprotic polar solvent having a dipole moment of 3 or more and 5 or less. Specifically, the amide-based solvent, and the lactone-based solvent are preferable, and it is more preferable to use N,N′-dimethylformamide (DMF), N,N′-dimethylacetamide (DMAc), or N-methylpyrrolidone (NMP). Further, when the solvent is a solvent having high volatility and a boiling point of 180° C. or lower at 1 atm, there is also an advantage that after the glass cloth 5 is impregnated with the liquid composition 9, the solvent is easily removed. From this viewpoint, DMF and DMAc are particularly preferable. Since the use of such an amide-based solvent makes it difficult to generate thickness variation and the like at the production of the glass cloth substrate 2, there is also an advantage that a conductor layer is easily formed on the glass cloth substrate 2.

When the above-mentioned aprotic solvent is used in the liquid composition 9, it is preferable that 20 to 50 parts by mass, preferably 22 to 40 parts by mass of the liquid crystal polyester 7 is dissolved in 100 parts by mass of this aprotic solvent. When the content of the liquid crystal polyester 7 based on this liquid composition 9 is in such a range, there is a tendency that, upon the production of the glass cloth substrate 2, the efficiency of impregnating the glass cloth 5 with the liquid composition 9 becomes favorable, and upon the removal of the solvent after impregnation by drying, a disadvantage of generation of thickness variation or the like occurs with difficulty.

One kind or two or more kinds of resins other than the liquid crystal polyester 7, such as thermoplastic resins including polypropylene, polyamide, polyester, polyphenylene sulfide, polyether ketone, polycarbonate, polyethersulfone, polyphenyl ether and modified products thereof, and polyetherimide; elastomers, a representative of which is a copolymer of glycidyl methacrylate and polyethylene; thermosetting resins including a phenolic resin, an epoxy resin, a polyimide resin, and a cyanate resin may be added to the liquid composition 9 in such a range that an object of the present invention is not deteriorated, provided that, even when such other resins are used, it is preferable that these other resins are also soluble to a solvent used in the liquid composition 9.

Fine foreign substances contained in this liquid composition 9 may be removed by a filtration treatment using a filter or the like, as necessary.

Further, this liquid composition 9 may be subjected to a defoaming treatment, as necessary.

When the liquid composition 9 has been prepared like this, operation progresses to a liquid composition impregnating step, and the previously surface-treated glass cloth 5 is impregnated with the previously prepared liquid composition 9, as shown in FIG. 1 (b).

Such impregnation can be carried out, for example, by preparing an immersion tank charged with the liquid composition 9, and immersing (soaking) the glass cloth 5 into this immersion tank. Herein, when the content of the liquid crystal polyester 7 in the liquid composition 9, the time of immersion in the immersion tank, and the rate of pulling up the glass cloth 5 impregnated with the liquid composition 9 are appropriately optimized, the amount of the above-mentioned preferable liquid crystal polyester 7 attached can be easily controlled.

When the glass cloth 5 has been impregnated with the liquid composition 9 like this, operation progresses to a substrate preparing step, and the solvent in the liquid composition 9 is removed to obtain the glass cloth substrate 2, as shown in FIG. 1 (c).

Thereupon, a process of removing the solvent is not particularly limited, but removal of the solvent by evaporation is preferable in that the operation is convenient, and a process performing heating, reduction in pressure, ventilation or a combination thereof is used. For the production of the glass cloth substrate 2, after removal of the solvent, a heat treatment may be further performed. According to such a heat treatment, the liquid crystal polyester 7 contained in the glass cloth substrate 2 after removal of the solvent can be further allowed to have high molecular weight. Examples of treatment conditions in connection with this heat treatment include a process of performing a heat treatment at 240 to 330° C. for 1 to 30 hours under an inert gas atmosphere such as nitrogen. In addition, from the viewpoint of obtaining the glass cloth substrate 2 having more favorable heat resistance, as the treatment conditions of this heat treatment, it is preferable that the heating temperature thereof is higher than 250° C., and it is furthermore preferable that the heating temperature is in a range of 260 to 320° C. It is preferable, in terms of productivity, that the treatment time of this heat treatment is selected from 1 to 60 hours.

The amount of the liquid crystal polyester 7 attached to the glass cloth substrate 2 after removal of the solvent is preferably 30 to 80 mass %, and more preferably 40 to 70 mass % based on the mass of the resulting glass cloth substrate 2.

Thereupon, the glass cloth 5 has been subjected to a surface treatment using a silane compound having a methacryloyloxy group in a molecule, as described above. For this reason, the heat resistance at moisture absorption of the glass cloth substrate 2 is improved, and the situation of pealing of the liquid crystal polyester 7 from the glass cloth 5 can be avoided. This is supposed that since this silane compound has a specific functional group, this silane compound functions as a coupling agent, to thereby improve adherability between an organic material (liquid crystal polyester 7) and an inorganic material (glass cloth 5), and therefore both of them are bonded firmly.

When the glass cloth substrate 2 has been obtained like this, operation progresses to a conductor pressure-attaching step, as shown in FIG. 1(d), and a copper foil 3 is pasted on a surface (FIG. 1 (d) upper surface) of the glass cloth substrate 2, and is pressed under the environment of high temperature and vacuum, to thereby perform the thermal pressure-attachment of the copper foil 3 on the glass cloth substrate 2.

When the copper foil 3 has been thermally pressure-attached on the glass cloth substrate 2 like this, operation progresses to a patterning step, as shown in FIG. 1(e), and an unnecessary part is removed from the copper foil 3 by etching, to thereby form a predetermined circuit pattern on the glass cloth substrate 2.

At this time point, a process for producing the printed wiring board 1 is terminated, and a printed wiring board 1 in which a circuit pattern is formed on one surface of the glass cloth substrate 2 is completed.

Since the heat resistance at moisture absorption of the glass cloth substrate 2 has been improved as described above, the reliance and durability of the thus produced printed wiring board 1 are enhanced.

### Other Embodiments of the Invention

In the above-mentioned embodiment 1, the printed wiring plate 1 in which a conductor layer (copper foil 3) is laminated on one surface of an insulating layer (glass cloth substrate 2) has been described, but the present invention can be also similarly applied in order to obtain a printed wiring board (not shown) in which a conductor layer is laminated on both surfaces of an insulating layer. That is, the present invention can be applied in order to obtain a printed wiring board in which a conductor layer is laminated on at least one surface of the insulating layer.

That is, the present invention can provide;

a printed wiring board including the glass cloth substrate (having a first surface and a second surface present on the rear surface of the first surface) and a conductor layer, and having at least one conductor layer on the first surface of the glass cloth substrate,

a printed wiring board further having a conductor layer on the second surface of the glass cloth substrate, in the above-mentioned printed wiring board having a conductor layer, and the like. Herein, the glass cloth substrate can have a function as an insulating layer.

In the above-mentioned embodiment 1, the monolayer-type printed wiring board 1 having one layer of an insulating layer (glass cloth substrate 2) has been described, but the present invention can be also similarly applied in order to obtain a multilayer-type printed wiring board (not shown) having two or more layers of insulating layers.

In the above-mentioned embodiment 1, the case where the liquid composition 9 including a solvent, the liquid crystal polyester 7 and the filler 6 is used upon the production of the printed wiring board 1 has been described, but it is also possible to use a liquid composition 9 including only a solvent and the liquid crystal polyester 7 without using the filler 6.

Further, in the above-mentioned embodiment 1, the printed wiring board 1 equipped with the copper foil 3 as a conductor layer has been described, but it is also possible to use a metal foil other than the copper foil 3 (e.g., gold foil, silver foil, aluminum foil, stainless foil etc.), a carbon graphite sheet, and others as substitutions for the conductor layer.

### EXAMPLES

The examples of the present invention will be described below. The present invention is not limited to the examples.

### Example 1

A reactor equipped with a stirring device, a torque meter, a nitrogen gas introducing tube, a thermometer and a reflux condenser was charged with 1976 g (10.5 mol) of 2-hydroxy-6-naphthoic acid, 1474 g (9.75 mol) of 4-hydroxyacetoanilide, 1620 g (9.75 mol) of isophthalic acid and 2374 g (23.25 mol) of acetic acid anhydride. After the interior of the reactor was sufficiently replaced with a nitrogen gas, temperature was raised to 150° C. over 15 minutes under a nitrogen gas stream, and the materials were refluxed for 3 hours while retaining that temperature.

Thereafter, the temperature was raised to 300° C. over 170 minutes while distilling acetic acid as a byproduct and unreacted acetic acid anhydride were distilled off, the time point at which an increase in a torque was recognized was regarded as reaction termination, and a content was taken out. After this content was cooled to room temperature, and ground with a grinder, to obtain powdery liquid crystal polyester with relatively low molecular weight. When the flow starting temperature of this powdery liquid crystal polyester was measured with a flow tester (“Model CFT-500” manufactured by Shimadzu Corporation), this flow starting temperature was 235° C. Solid phase polymerization was performed, in which this powdery liquid crystal polyester was subjected to heat-treatment at 223° C. for 3 hours in a nitrogen atmosphere. The liquid crystal polyester had a flow starting temperature of, after solid phase polymerization, 270° C.

The thus obtained liquid crystal polyester (2200 g) was added to 7800 g of N,N-dimethylacetamide (DMAc), and the mixture was heated at 100° C. for 2 hours to obtain a liquid composition. When the melt viscosity of this liquid composition was measured at a measuring temperature of 23° C. using a B-type viscometer (“Model TVL-20” manufactured by TOKI SANGO CO., LTD., Rotor No. 21 (rotation rate: 5 rpm)), this liquid composition had a melt viscosity of 200 cP.

On the other hand, to 594 g of pure water were added 0.5 g of acetic acid and 6 g of 3-methacryloyloxypropylmethyldimethoxysilane (“KBM-502” manufactured by Shin-Etsu Chemical Co., Ltd.), and the mixture was stirred at room temperature for 30 minutes at 200 rpm to produce a 1 mass % aqueous solution. In this 1 mass % aqueous solution was immersed a glass cloth (glass cloth of Arisawa Manufacturing Co., Ltd.; 2116 under IPC's name) over 30 minutes, and the resultant was dried with a circulation drier at 100° C. over 20 minutes.

The thus obtained surface-treated glass cloth was impregnated with the previous liquid composition at room temperature over 1 minute, and the solvent was evaporated with a hot air drier under the condition of a set temperature of 160° C. to obtain a glass cloth substrate. The amount of a resin attached to this glass cloth substrate was about 35 mass %, and the thickness thereof was 100 μm. A heat treatment was performed with a hot air drier at 290° C. for 3 hours under a nitrogen atmosphere. Then, a copper foil (“3EC-VLP” manufactured by MITSUI MINING & SMELTING CO., LTD (thickness 18 μm)) was laminated on both surfaces of the glass cloth substrate. The resultant was integrated by thermally pressing the resultant with a high temperature vacuum pressing machine (“KVHC-PRESS” manufactured by KITAGAWA SEIKI Co., Ltd., longitudinal length: 300 mm, transverse length: 300 mm) under the condition of a temperature of 340° C. and a pressure of 5 MPa over 30 minutes, to thereby obtain a metal foil laminate. Thereafter, using an aqueous ferric chloride solution (manufactured by Kida Co., Ltd., 40° baume), the copper foil of this metal foil laminate was removed by etching to obtain an evaluation substrate with 5 cm square.

### Example 2

An evaluation substrate with 5 cm square was obtained in the same manner as in Example 1 except for using 3-methacryloyloxypropyltrimethoxysilane (“KBM-503” manufactured by Shin-Etsu Chemical Co., Ltd.) in place of 3-methacryloyloxypropylmethyldimethoxysilane as the silane compound for the surface treatment of the glass cloth.

### Comparative Example 1

An evaluation substrate with 5 cm square was obtained in the same manner as in Example 1 except for omitting a step of surface-treating the glass cloth.

### Comparative Example 2

An evaluation substrate with 5 cm square was obtained in the same manner as in Example 1 except for using 3-acryloyloxypropyltrimethoxysilane (“KBM-5103” manufactured by Shin-Etsu Chemical Co., Ltd.) in place of 3-methacryloyloxypropylmethyldimethoxysilane as the silane compound for the surface treatment of the glass cloth.

### Comparative Example 3

An evaluation substrate with 5 cm square was obtained in the same manner as in Example 1 except for using 2-(3,4-epoxycyclohexyl)ethyltrimethoxysilane (“KBM-303” manufactured by Shin-Etsu Chemical Co., Ltd.) in place of 3-methacryloyloxypropylmethyldimethoxysilane as the silane compound for the surface treatment of the glass cloth.

### Comparative Example 4

An evaluation substrate with 5 cm square was obtained in the same manner as in Example 1 except for using 3-glycidoxypropyltrimethoxysilane (“KBM-403” manufactured by Shin-Etsu Chemical Co., Ltd.) in place of 3-methacryloyloxypropylmethyldimethoxysilane as the silane compound for the surface treatment of the glass cloth.

### Comparative Example 5

An evaluation substrate with 5 cm square was obtained in the same manner as in Example 1 except for using 3-glycidoxypropyltriethoxysilane (“KBE-403” manufactured by Shin-Etsu Chemical Co., Ltd.) in place of 3-methacryloyloxypropylmethyldimethoxysilane as the silane compound for the surface treatment of the glass cloth.

### Comparative Example 6

An evaluation substrate with 5 cm square was obtained in the same manner as in Example 1 except for using 3-aminopropyltriethoxysilane (“KBE-903” manufactured by Shin-Etsu Chemical Co., Ltd.) in place of 3-methacryloyloxypropylmethyldimethoxysilane as the silane compound for the surface treatment of the glass cloth.

### Comparative Example 7

An evaluation substrate with 5 cm square was obtained in the same manner as in Example 1 except for using 3-ureidopropyltriethoxysilane (“KBE-585” manufactured by Shin-Etsu Chemical Co., Ltd.) in place of 3-methacryloyloxypropylmethyldimethoxysilane as the silane compound for the surface treatment of the glass cloth.

### Comparative Example 8

An evaluation substrate with 5 cm square was obtained in the same manner as in Example 1 except for using methyltrimethoxysilane (“Z-6366” manufactured by Dow Corning Toray Co., Ltd.) in place of 3-methacryloyloxypropylmethyldimethoxysilane as the silane to compound for the surface treatment of the glass cloth.

### Comparative Example 9

An evaluation substrate with 5 cm square was obtained in the same manner as in Example 1 except for using phenyltrimethoxysilane (“Z-6124” manufactured by Dow Corning Toray Co., Ltd.) in place of 3-methacryloyloxypropylmethyldimethoxysilane as the silane compound for the surface treatment of the glass cloth.

### <Evaluation of Heat Resistance at Moisture Absorption>

Regarding each of Examples 1 and 2 and Comparative Examples 1 to 9, the evaluation substrate was treated in a furnace at 121° C., 2 atm (atmospheric pressure) and a relative humidity of 100% over 2 hours, and this evaluation substrate was immersed in a solder bath at 260° C. over 30 seconds. Across section of this evaluation substrate was observed with a digital microscope (“VH-8000” manufactured by KEYENCE CORPORATION), and it was confirmed whether or not there was pealing between the liquid crystal polyester and the glass cloth.

The results are summarized and shown in Table 1. In the column of “heat resistance at moisture absorption” in Table 1, when pealing between the liquid crystal polyester and the glass cloth was not confirmed, this is expressed as O, and when pealing between the liquid crystal polyester and the glass cloth was confirmed, this is expressed as x.

TABLE 1

| | | Heat |
|---|---|---|
| | | resistance |
| | | at moisture |
| | Silane compound | absorption |
| Example 1 | 3-Methacryloyloxypropylmethyl- | ∘ |
| | dimethoxysilane | |
| Example 2 | 3-Methacryloyloxypropyl- | ∘ |
| | trimethoxysilane | |
| Comparative | (Coupling agent was not added) | x |
| Example 1 | | |
| Comparative | 3-Acryloyloxypropyltrimethoxysilane | x |
| Example 2 | | |
| Comparative | 2-(3,4-Epoxycyclohexyl)ethyltri- | x |
| Example 3 | methoxysilane | |
| Comparative | 3-Glycidoxypropyltrimethoxysilane | x |
| Example 4 | | |
| Comparative | 3-Glycidoxypropyltriethoxysilane | x |
| Example 5 | | |
| Comparative | 3-Aminopropyltriethoxysilane | x |
| Example 6 | | |
| Comparative | 3-Ureidopropyltriethoxysilane | x |
| Example 7 | | |
| Comparative | Methyltrimethoxysilane | x |
| Example 8 | | |
| Comparative | Phenyltrimethoxysilane | x |
| Example 9 | | |

As apparent from Table 1, in all of Comparative Examples 1 to 9, pealing between the liquid crystal polyester and the glass cloth was confirmed, resulting in low heat resistance at moisture absorption of the glass cloth substrate. To the contrary, in all of Examples 1 and 2, pealing between the liquid crystal polyester and the glass cloth was not confirmed, and it was found out that the heat resistance at moisture absorption of the glass cloth substrate was high.

### INDUSTRIAL APPLICABILITY

The present invention can be widely applied to a printed wiring board (which may be either a multilayer type one or a monolayer type one) used in various utilities for communication, electric source, adaptation to cars and the like.

### EXPLANATION OF REFERENCE NUMERALS

1 Printed wiring board
2 Glass cloth substrate (insulating layer)
3 Copper foil (conductor layer)
5 Glass cloth
6 Filler
7 Liquid crystal polyester
9 Liquid composition

1. A process for producing a glass cloth substrate including a glass cloth which has been subjected to a surface treatment using a silane compound having a methacryloyloxy group, and a liquid crystal polyester contained in the glass cloth, comprising:
an impregnating step of impregnating the surface-treated glass cloth with a liquid composition including a solvent and the liquid crystal polyester to obtain a liquid composition-impregnated glass cloth, and
a substrate preparing step of removing the solvent from the liquid composition in the liquid composition-impregnated glass cloth to obtain a glass cloth substrate.

2. The process for producing a glass cloth substrate according to claim 1, wherein the liquid crystal polyester is a liquid crystal polyester having a structural unit shown by the following formula (1), a structural unit shown by the following formula (2), and a structural unit shown by the following formula (3), the content of the structural unit shown by the formula (1) being 30 to 50 mole %, the content of the structural unit shown by the formula (2) being 25 to 35 mole %, and the content of the structural unit shown by the formula (3) being 25 to 35 mole % based on the total of all structural units;
—O—Ar¹—CO— (1)
—CO—Ar²—CO— (2)
—X—Ar³—Y— (3)
wherein, Ar¹ represents a phenylene group or a naphthylene group, Ar² represents a phenylene group, a naphthylene group or a group represented by the following formula (4), Ar³ represents a phenylene group or a group represented by the formula (4), and X and Y each independently represent O or NH. A hydrogen atom bonded to the aromatic ring of each Ar¹, Ar² and Ar³ may be substituted with a halogen atom, an alkyl group or an aryl group;
—Ar¹¹—Z—Ar¹²— (4)
wherein, Ar¹¹ and Ar¹² each independently represent a phenylene group or a naphthylene group, and Z represents O, CO or SO₂.

3. The process for producing a glass cloth substrate according to claim 2, wherein at least one of X and Y in the structural unit shown by the formula (3) is NH.

4. The process for producing a glass cloth substrate according to claim 2, wherein the liquid crystal polyester is a liquid crystal polyester having a structural unit derived from a compound selected from the group consisting of p-hydroxybenzoic acid and 2-hydroxy-6-naphthoic acid as the structural unit shown by the formula (1), having a structural unit derived from a compound selected from the group consisting of terephthalic acid, isophthalic acid and 2,6-naphthalenedicarboxylic acid as the structural unit shown by the formula (2), and having a structural unit derived from p-aminophenol as the structural unit shown by the formula (3).

5. A printed wiring board comprising a glass cloth substrate obtained by the process for producing a glass cloth substrate according to claim 1 and a conductor layer, wherein the glass cloth substrate has a first surface and a second surface present on the rear side of the first surface, and the glass cloth substrate has the conductor layer on the first surface.

6. The printed wiring board according to claim 5, further comprising a conductor layer laminated on the second surface of the glass cloth substrate.

7. A printed wiring board comprising a plurality of glass cloth substrates, wherein at least one glass cloth substrate is a glass cloth substrate obtained by the process as defined in claim 1.
